(19) United States
(12) Patent Application Publication
(10) Pub. No.: US 2019/0212597 A1
(43) Pub. Date: Jul. 11, 2019

(54) Low Haze Liquid Crystal Materials

(71) Applicant: DigiLens, Inc., Sunnyvale, CA (US)

(72) Inventors: Jonathan David Waldern, Los Altos Hills, CA (US); Shibu Abraham, Sunnyvale, CA (US)

(73) Assignee: DigiLens, Inc., Sunnyvale, CA (US)

(21) Appl. No.: 16/242,943

(22) Filed: Jan. 8, 2019

Related U.S. Application Data
(60) Provisional application No. 62/614,813, filed on Jan. 8, 2018.

(51) Int. Cl. G02F 1/1334; G02F 1/13; C09K 19/54; G03F 7/00

(52) U.S. Cl. CPC G02F 1/13342; G02F 1/1326; C09K 2019/521; G03F 7/001; C09K 19/544

(57) ABSTRACT

Photopolymerizable materials and in particular holographic polymer dispersed liquid crystal materials and processes for fabricating holographic waveguide devices from such materials are provided. Materials and formulations of photopolymerizable materials are sufficiently low haze to allow for the omission of adhesives from within the cell of the holographic waveguide devices. The photopolymerizable materials are used in association with methods of manufacturing holographic waveguides such that photopolymerizable materials may be used as an adhesive material.

### CROSS-REFERENCE TO RELATED APPLICATIONS

The current application claims the benefit of and priority under 35 U.S.C. § 119(e) to U.S. Provisional Patent Application No. 62/614,813 entitled “Low Haze liquid Crystal Materials,” filed Jan. 8, 2018. The disclosure of U.S. Provisional Patent Application No. 62/614,813 is hereby incorporated by reference in its entirety for all purposes.

### FIELD OF THE INVENTION

The invention is generally directed to photopolymerizable dispersed liquid crystal materials and formulations of such materials for use in forming holographic waveguides.

### BACKGROUND OF THE INVENTION

Waveguides can be referred to as structures with the capability of confining and guiding waves (i.e., restricting the spatial region in which waves can propagate). One subclass includes optical waveguides, which are structures that can guide electromagnetic waves, typically those in the visible spectrum. Waveguide structures can be designed to control the propagation path of waves using a number of different mechanisms. For example, planar waveguides can be designed to utilize diffraction gratings to diffract and couple incident light into the waveguide structure such that the in-coupled light can proceed to travel within the planar structure via total internal reflection (“TIR”).

Fabrication of waveguides can include the use of material systems that allow for the recording of holographic optical elements within the waveguides. One class of such material includes polymer dispersed liquid crystal (“PDLC”) mixtures, which are mixtures containing photopolymerizable monomers and liquid crystals. A further subclass of such mixtures includes holographic polymer dispersed liquid crystal (“HPDLC”) mixtures. Holographic optical elements, such as volume phase gratings, can be recorded in such a liquid mixture by illuminating the material with two mutually coherent laser beams. During the recording process, the monomers polymerize and the mixture undergoes a photopolymerization-induced phase separation, creating regions densely populated by liquid crystal micro-droplets, interspersed with regions of clear polymer. The alternating liquid crystal-rich and liquid crystal-depleted regions form the fringe planes of the grating.

Waveguide optics, such as those described above, can be considered for a range of display and sensor applications. In many applications, waveguides containing one or more grating layers encoding multiple optical functions can be realized using various waveguide architectures and material systems, enabling new innovations in near-eye displays for augmented reality (“AR”) and virtual reality (“VR”), compact heads-up displays (“HUDs”) for aviation and road transport, and sensors for biometric and laser radar (“LIDAR”) applications.

### SUMMARY OF THE INVENTION

One embodiment includes a method of forming a waveguide cell, the method including providing first and second transparent substrates, forming a cell from the substrates, providing a reactive monomer liquid crystal mixture material including photopolymerizable monomers, a cross-linking agent, a photoinitiator, and liquid crystals, combining at least one of the monomers and at least one of the liquid crystals, heating the reactive monomer liquid crystal mixture material to a temperature sufficient to initiate crosslinking of the polymer matrix, and depositing the heated reactive monomer liquid crystal mixture material into the cell.

In another embodiment, the method further includes exposing the filled cell to a light source to pre-cure the reactive monomer liquid crystal mixture material.

In a further embodiment, the method further includes cooling the pre-cured cell to freeze the reactive monomer liquid crystal mixture material material.

In still another embodiment, the method further includes exposing the cell using a laser wavelength holographic process.

In a still further embodiment, the method further includes heating the exposed cell to an elevated temperature and curing the exposed cell.

In yet another embodiment, the at least one of the monomers and the at least one of the liquid crystals are combined using a vibrational technique.

In a yet further embodiment, the heated reactive monomer liquid crystal mixture material is deposited into the cell using a multi-step vibrational technique.

In another additional embodiment, the deposited heated reactive monomer liquid crystal mixture material functions as an adhesive in the cell.

In a further additional embodiment, the reactive monomer liquid crystal mixture material further includes at least one nanoparticle.

In another embodiment again, the at least one nanoparticle includes a one of a carbon nanotube or a nanoclay nanoparticle.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings, which forms a part of this disclosure.

### BRIEF DESCRIPTION OF THE DRAWINGS

The description will be more fully understood with reference to the following figures and data graphs, which are presented as exemplary embodiments of the invention and should not be construed as a complete recitation of the scope of the invention. It will apparent to those skilled in the art that the present invention may be practiced with some or all of the present invention as disclosed in the following description.

FIGS. 1A and 1B conceptually illustrate two volume Bragg grating configurations in accordance with various embodiments of the invention.

FIG. 2 conceptually illustrates a surface relief grating in accordance with an embodiment of the invention.

FIGS. 3A and 3B conceptually illustrate HPDLC SBG devices and the switching property of SBGs in accordance with various embodiments of the invention.

FIGS. 4A-4D conceptually illustrate two-beam recording processes in accordance with various embodiments of the invention.

FIG. 5 conceptually illustrates a single-beam recording process utilizing an amplitude grating in accordance with an embodiment of the invention.

FIG. 6 shows an image of a RMLCM material used as an adhesive in accordance with an embodiment of the invention.

FIG. 7 conceptually illustrates a schematic of a flow chart illustrating a method of filling a waveguide cell using an RMLCM material as an adhesive in accordance with an embodiment of the invention.

FIGS. 8 and 9 conceptually illustrate schematics of flow charts illustrating methods of forming HPDLC devices in accordance with various embodiments of the invention.

### DETAILED DESCRIPTION

For the purposes of describing embodiments, some well-known features of optical technology known to those skilled in the art of optical design and visual displays have been omitted or simplified in order to not obscure the basic principles of the invention. Unless otherwise stated the term “on-axis” in relation to a ray or a beam direction refers to propagation parallel to an axis normal to the surfaces of the optical components described in relation to the invention. In the following description the terms light, ray, beam, and direction may be used interchangeably and in association with each other to indicate the direction of propagation of electromagnetic radiation along rectilinear trajectories. The term light and illumination may be used in relation to the visible and infrared bands of the electromagnetic spectrum. Parts of the following description will be presented using terminology commonly employed by those skilled in the art of optical design. As used herein, the term grating may encompass a grating comprised of a set of gratings in some embodiments. For illustrative purposes, it is to be understood that the drawings are not drawn to scale unless stated otherwise.

Turning now to the drawings, photopolymerizable materials and in particular holographic polymer dispersed liquid crystal materials and processes for fabricating holographic waveguide devices from such materials are provided. In many embodiments, materials and formulations of photopolymerizable materials are designed for use in recording processes for waveguide applications. Such materials and mixtures can be used in the construction of waveguide cells. Once constructed, such cells can be used in recording processes for the recording of various optical elements, such as but not limited to volume gratings. In some embodiments, materials and formulations of photopolymerizable materials are sufficiently low haze to allow for the omission of adhesives from within the cell of the holographic waveguide devices. In various embodiments, the photopolymerizable materials are used in association with methods of manufacturing holographic waveguides such that photopolymerizable materials may be used as an adhesive material. In many embodiments the cells may be formed with or without spacers. Waveguide structures and gratings, waveguide cells, recording processes, and material formulations are discussed below in further detail.

### Waveguide Structures

Waveguide structures in accordance with various embodiments can be implemented in many different ways. In many embodiments, the waveguide structures are designed to be optical waveguides, which are structures that can confine and guide electromagnetic waves in the visible spectrum, or light. These optical waveguides can be implemented for use in a number of different applications, such as but not limited to helmet mounted displays, head mounted displays (“HMDs”), and HUDs. The term HUD is typically utilized to describe a class of devices that incorporates a transparent display that presents data without requiring users to change their usual visual field. Optical waveguides can integrate various optical functions into a desired form factor depending on the given application.

Optical waveguides in accordance with various embodiments can be designed to manipulate light waves in a controlled manner using various methods and waveguide optics. For example, optical waveguides can be implemented using materials with higher refractive indices than the surrounding environment to restrict the area in which light can propagate. Light coupled into optical waveguides made of such materials at certain angles can be confined within the waveguide via total internal reflection. In a planar waveguide, the angles at which total internal reflection occurs can be given by Snell's law, which can determine whether the light is refracted or entirely reflected at the surface boundary.

In many embodiments, waveguides incorporating Bragg gratings are implemented for HUD applications. HUDs can be incorporated in any of a variety of applications including (but not limited to) near-eye applications. HUDs that utilize planar waveguides incorporating Bragg gratings in accordance with various embodiments of the invention can achieve significantly larger fields of view and have lower volumetric requirements than HUDs implemented using conventional optical components. In some embodiments, the HUDs include at least one waveguide incorporating a number of gratings. In further embodiments, the waveguide incorporates at least three Bragg gratings that can be implemented to provide various optical functions, such as but not limited to dual-axis beam expansion. For example, in a number of embodiments, the waveguide incorporates an input grating, a fold grating, and an output grating. HUDs utilizing waveguides can be implemented using varying numbers of waveguide. In many embodiments, a HUD is implemented using a single waveguide. In other embodiments, the HUD is implemented using a stack of waveguides. Multiple waveguides can be stacked and implemented to provide different optical functions, such as but not limited to implementing color displays. In several embodiments, the HUDs incorporate three separate waveguides, one waveguide for each of a Red, Green, and Blue color channel.

Waveguides utilizing Bragg gratings in accordance with various embodiments of the invention can be designed to have different types of fringes. Use of multiple waveguides having the same surface pitch sizes but different grating slanted angles can increase the overall couple-in angular bandwidth of the waveguide. In a number of embodiments, one or more of the gratings within the waveguide incorporate a rolling K-vector and/or a slant angle that varies across the grating to modify the diffraction efficiency of the grating. The K-vector can be defined as a vector orthogonal to the plane of the associated grating fringe, which can determine the optical efficiency for a given range of input and diffracted angles. By incorporating a grating with rolled K-vectors (“RKVs”), the gratings can be designed to vary diffraction efficiency in a manner that achieves desirable characteristics across the eyebox of the HUD display. Configurations of grating fringes (such as RKVs) and other aspects relating to the structures and implementations of waveguides for use in HUDs are discussed below in further detail.

Diffraction Gratings

Optical waveguides can incorporate different optical elements to manipulate the propagation of light waves. As can readily be appreciated, the type of grating selected can depend on the specific requirements of a given application. Optical structures recorded in waveguides can include many different types of optical elements, such as but not limited to diffraction gratings. In many embodiments, the grating implemented is a Bragg grating (also referred to as a volume grating). Bragg gratings can have high efficiency with little light being diffracted into higher orders. The relative amount of light in the diffracted and zero order can be varied by controlling the refractive index modulation of the grating, a property that is can be used to make lossy waveguide gratings for extracting light over a large pupil. By strategically placing volume Bragg gratings within a waveguide, the propagation of light within the waveguide can be affected in a controlled manner to achieve various effects. The diffraction of light incident on the grating can be determined by the characteristic of the light and the grating. As can readily be appreciated, volume Bragg gratings can be constructed to have different characteristics depending on the specific requirements of the given application. In a number of embodiments, the volume Bragg grating is designed to be a transmission grating. In other embodiments, the volume Bragg grating is designed to be a reflection grating. In transmission gratings, incident light meeting the Bragg condition is diffracted such that the diffracted light exits the grating on the side which the incident light did not enter. For reflection gratings, the diffracted light exits on the same side of the grating as where the incident light entered.

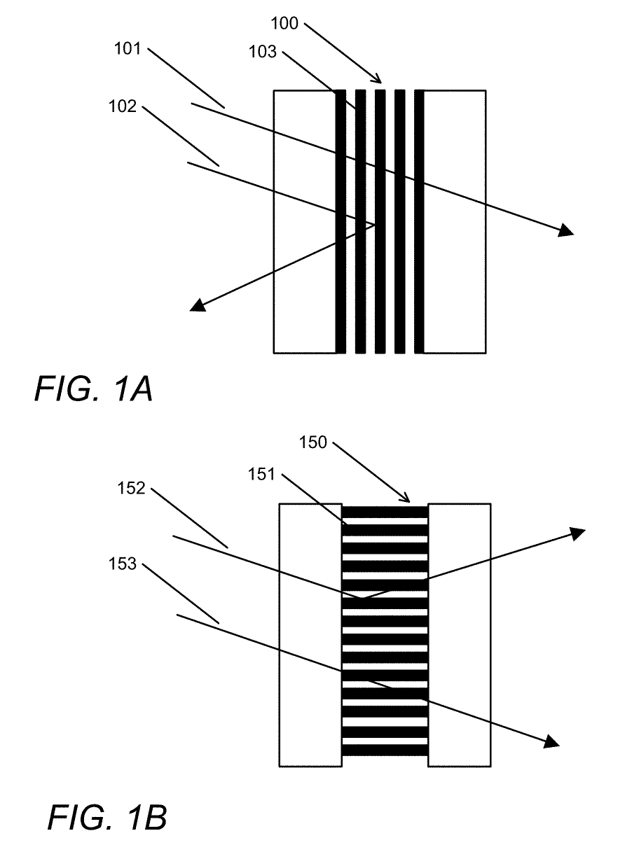

FIGS. 1A and 1B conceptually illustrate two volume Bragg grating configurations in accordance with various embodiments of the invention. Depending on the side out of which a light ray exits after diffraction, the grating can be classified as either a reflection grating 100 or a transmission grating 150. The conditions for refraction/reflection, or Bragg condition, can depend several factors, such as but not limited to the refractive indices of the medium, the grating period, the wavelength of the incident light, and the angle of incidence. FIG. 1A shows a reflection grating 100 recorded in a transparent material. As shown, light rays 101, 102 are of different wavelengths and are incident at the same angle on the reflection grating 100, which has fringes 103 that are parallel to the grating surface. Light ray 101 does not meet the Bragg condition and is transmitted through the grating. On the other hand, light ray 102 does meet the Bragg condition and is reflected back through the same surface on which it entered. Another type of grating is a transmission grating, which is conceptually illustrated in FIG. 1B. In the illustrative embodiment, the transmission grating 150 has fringes 151 that are perpendicular to the grating surface. As shown, light rays 152, 153 with different wavelengths are incident on the transmission grating 150 at the same angle. Light ray 152 meets the Bragg condition and is refracted, exiting on the opposite side of the grating on which the light ray 152 entered. Light ray 153 does not meet the Bragg condition and is transmitted through with its original path of propagation. Depending on the efficiency of the grating, light can be partially reflected or refracted. Although FIGS. 1A and 1B illustrate specific volume grating structures, any type of grating structure can be recorded in a waveguide cell in accordance with various embodiments of the invention. For example, volume gratings can be implemented with fringes that are tilted and/slanted relative to the grating surface, which can affect the angles of diffraction/reflection. Although the discussions above denote the grating structures as either transmission or reflection, both types of gratings behave in the same manner according to the standard grating equation.

Waveguide structures in accordance with various embodiments of the invention can implement gratings in a number of different ways. In addition to volume gratings, gratings can be implemented as surface relief gratings. As the name suggests, surface relief gratings can be implemented by physically forming grooves or periodic patterns on the surface of the substrate. The periodicity and angles formed by the grooves can determine the efficiency and other characteristics of the grating. Any of a number of methods can be used to form these grooves, such as but not limited to etching and photolithography.

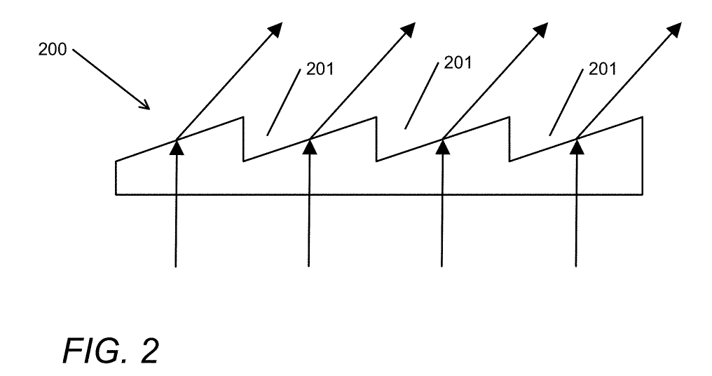

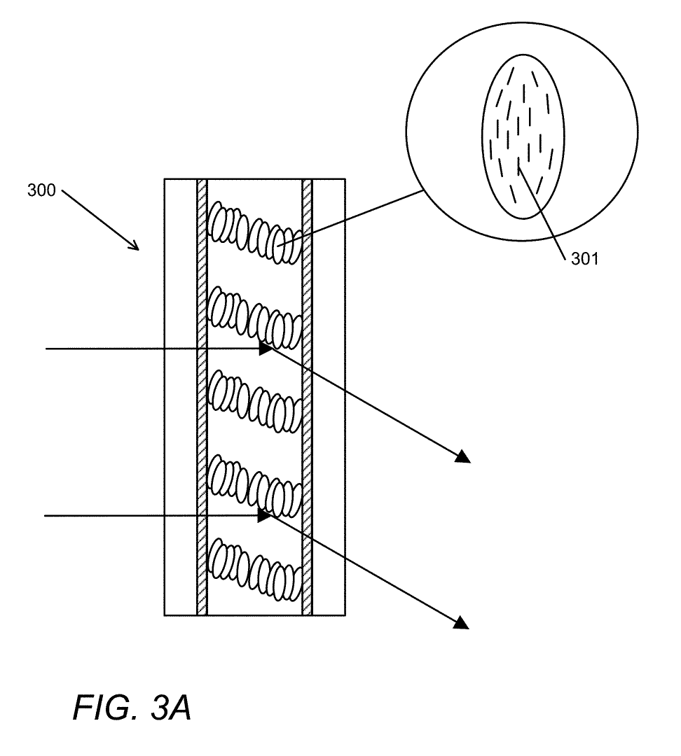

FIG. 2 conceptually illustrates a surface relief grating in accordance with an embodiment of the invention. As shown, the surface relief grating 200 contains periodic slanted grooves 201. When light is incident on the grooves 201, diffraction can occur under certain conditions. The slant and periodicity of the grooves 201 can be designed to achieve targeted diffraction behavior of incident light.

Although FIGS. 1A-1B and 2 show specific grating structures, it is readily appreciable that grating structures can be configured in a number of different ways depending on the specific requirements of a given application. Examples of such configurations are discussed in the sections below in further detail.

Switchable Bragg Gratings

One class of gratings used in holographic waveguide devices is the Switchable Bragg Grating (“SBG”). SBGs can be fabricated by first placing a thin film of a mixture of photopolymerizable monomers and liquid crystal material between glass plates or substrates. In many cases, the glass plates are in a parallel configuration. One or both glass plates can support electrodes, typically transparent tin oxide films, for applying an electric field across the film. The grating structure in an SBG can be recorded in the liquid material (often referred to as the syrup) through photopolymerization-induced phase separation using interferential exposure with a spatially periodic intensity modulation. Factors such as but not limited to control of the irradiation intensity, component volume fractions of the materials in the mixture, and exposure temperature can determine the resulting grating morphology and performance. As can readily be appreciated, a wide variety of materials and mixtures can be used depending on the specific requirements of a given application. In many embodiments, HPDLC material is used. During the recording process, the monomers polymerize and the mixture undergoes a phase separation. The LC molecules aggregate to form discrete or coalesced droplets that are periodically distributed in polymer networks on the scale of optical wavelengths. The alternating liquid crystal-rich and liquid crystal-depleted regions form the fringe planes of the grating, which can produce Bragg diffraction with a strong optical polarization resulting from the orientation ordering of the LC molecules in the droplets.

The resulting volume phase grating can exhibit very high diffraction efficiency, which can be controlled by the magnitude of the electric field applied across the film. When an electric field is applied to the grating via transparent electrodes, the natural orientation of the LC droplets can change, causing the refractive index modulation of the fringes to lower and the hologram diffraction efficiency to drop to very low levels. Typically, the electrodes are configured such that the applied electric field will be perpendicular to the substrates. In a number of embodiments, the electrodes are fabricated from indium tin oxide (“ITO”). In the OFF state with no electric field applied, the extraordinary axis of the liquid crystals generally aligns normal to the fringes. The grating thus exhibits high refractive index modulation and high diffraction efficiency for P-polarized light. When an electric field is applied to the HPDLC, the grating switches to the ON state wherein the extraordinary axes of the liquid crystal molecules align parallel to the applied field and hence perpendicular to the substrate. In the ON state, the grating exhibits lower refractive index modulation and lower diffraction efficiency for both S- and P-polarized light. Thus, the grating region no longer diffracts light. Each grating region can be divided into a multiplicity of grating elements such as for example a pixel matrix according to the function of the HPDLC device. Typically, the electrode on one substrate surface is uniform and continuous, while electrodes on the opposing substrate surface are patterned in accordance to the multiplicity of selectively switchable grating elements.

Typically, the SBG elements are switched clear in 30 μs with a longer relaxation time to switch ON. Note that the diffraction efficiency of the device can be adjusted, by means of the applied voltage, over a continuous range. In many cases, the device exhibits near 100% efficiency with no voltage applied and essentially zero efficiency with a sufficiently high voltage applied. In certain types of HPDLC devices, magnetic fields can be used to control the LC orientation. In some HPDLC applications, phase separation of the LC material from the polymer can be accomplished to such a degree that no discernible droplet structure results. An SBG can also be used as a passive grating. In this mode, its chief benefit is a uniquely high refractive index modulation. SBGs can be used to provide transmission or reflection gratings for free space applications. SBGs can be implemented as waveguide devices in which the HPDLC forms either the waveguide core or an evanescently coupled layer in proximity to the waveguide. The glass plates used to form the HPDLC cell provide a total internal reflection (“TIR”) light guiding structure. Light can be coupled out of the SBG when the switchable grating diffracts the light at an angle beyond the TIR condition.

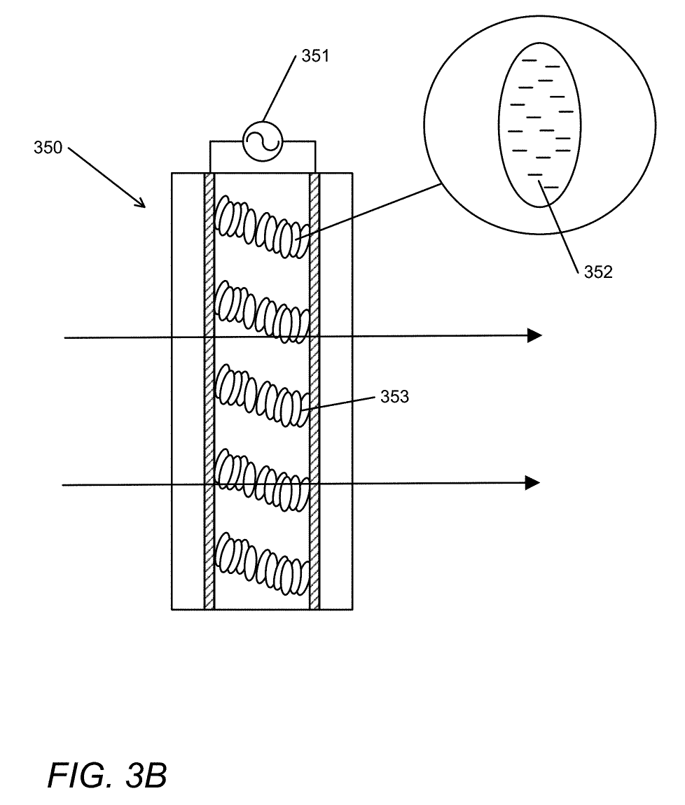

FIGS. 3A and 3B conceptually illustrate HPDLC SBG devices 300, 350 and the switching property of SBGs in accordance with various embodiments of the invention. In FIG. 3A, the SBG 300 is in an OFF state. As shown, the LC molecules 301 are aligned substantially normal to the fringe planes. As such, the SBG 300 exhibits high diffraction efficiency, and incident light can easily be diffracted. FIG. 3B illustrates the SBG 350 in an ON position. An applied voltage 351 can orient the optical axis of the LC molecules 352 within the droplets 353 to produce an effective refractive index that matches the polymer's refractive index, essentially creating a transparent cell where incident light is not diffracted. In the illustrative embodiment, an AC voltage source is shown. As can readily be appreciated, various voltage sources can be utilized depending on the specific requirements of a given application.

In waveguide cell designs, in addition to the components described above, adhesives and spacers can be disposed between the substrates to affix the layers of the elements together and to maintain the cell gap, or thickness dimension. In these devices, spacers can take many forms, such as but not limited to materials, sizes, and geometries. Materials can include, for example, plastics (e.g., divinylbenzene), silica, and conductive spacers. They can take any suitable geometry, such as but not limited to rods and spheres. The spacers can take any suitable size. In many cases, the sizes of the spacers range from 1 to 30 μm. While the use of these adhesive materials and spacers can be necessary in LC cells using conventional materials and methods of manufacture, they can contribute to the haziness of the cells degrading the optical properties and performance of the waveguide and device.

### Waveguide Cells

A waveguide cell can be defined as a device containing uncured and/or unexposed optical recording material in which optical elements, such as but not limited to gratings, can be recorded. In many embodiments, optical elements can be recorded in the waveguide cell by exposing the optical recording material to certain wavelengths of electromagnetic radiation. Typically, a waveguide cell is constructed such that the optical recording material is sandwiched between two substrates, creating a three-layer waveguide cell. Depending on the application, waveguide cells can be constructed in a variety of configurations. In some embodiments, the waveguide cell contains more than three layers. In a number of embodiments, the waveguide cell contains different types of layers that can serve various purposes. For example, waveguide cells can include protective cover layers, polarization control layers, and alignment layers.

Substrates of varying materials and shapes can be used in the construction of waveguide cells. In many embodiments, the substrates are plates made of a transparent material, such as but not limited to glass and plastics. Substrates of different shapes, such as but not limited to rectangular and curvilinear shapes, can be used depending on the application. The thicknesses of the substrates can also vary depending on the application. Oftentimes, the shapes of the substrates can determine the overall shape of the waveguide. In a number of embodiments, the waveguide cell contains two substrates that are of the same shape. In other embodiments, the substrates are of different shapes. As can readily be appreciated, the shapes, dimensions, and materials of the substrates can vary and can depend on the specific requirements of a given application.

In many embodiments, beads, or other particles, are dispersed throughout the optical recording material to help control the thickness of the layer of optical recording material and to help prevent the two substrates from collapsing onto one another. In some embodiments, the waveguide cell is constructed with an optical recording layer sandwiched between two planar substrates. Depending on the type of optical recording material used, thickness control can be difficult to achieve due to the viscosity of some optical recording materials and the lack of a bounding perimeter for the optical recording layer. In a number of embodiments, the beads are relatively incompressible solids, which can allow for the construction of waveguide cells with consistent thicknesses. The size of a bead can determine a localized minimum thickness for the area around the individual bead. As such, the dimensions of the beads can be selected to help attain the desired optical recording layer thickness. The beads can be made of any of a variety of materials, including but not limited to glass and plastics. In several embodiments, the material of the beads is selected such that its refractive index does not substantially affect the propagation of light within the waveguide cell.

In some embodiments, the waveguide cell is constructed such that the two substrates are parallel or substantially parallel. In such embodiments, relatively similar sized beads can be dispersed throughout the optical recording material to help attain a uniform thickness throughout the layer. In other embodiments, the waveguide cell has a tapered profile. A tapered waveguide cell can be constructed by dispersing beads of different sizes across the optical recording material. As discussed above, the size of a bead can determine the local minimum thickness of the optical recording material layer. By dispersing the beads in a pattern of increasing size across the material layer, a tapered layer of optical recording material can be formed when the material is sandwiched between two substrates.

Waveguide cells can be constructed using a variety of different methods. In many embodiments, a waveguide cell is constructed by coating a first substrate with an optical recording material capable of acting as an optical recording medium. In a number of embodiments, the optical recording material is deposited onto the substrate using spin coating or spraying. A second substrate layer can be incorporated to form the waveguide cell such that the optical recording material is sandwiched between two substrates. In several embodiments, the second substrate can be a thin protective film coated onto the exposed layer. In various embodiments, the substrates are used to make a cell, which is then filled with the optical recording material. The filling process can be accomplished using a variety of different methods, such as but not limited vacuum filling methods. In further embodiments, alignment layers and/or polarization layers can be added.

### HPDLC Material Systems

HPDLC mixtures in accordance with various embodiments of the invention generally include LC, monomers, photoinitiator dyes, and coinitiators. The mixture (often referred to as syrup) frequently also includes a surfactant. For the purposes of describing the invention, a surfactant is defined as any chemical agent that lowers the surface tension of the total liquid mixture. The use of surfactants in PDLC mixtures is known and dates back to the earliest investigations of PDLCs. For example, a paper by R. L Sutherland et al., SPIE Vol. 2689, 158-169, 1996, the disclosure of which is incorporated herein by reference, describes a PDLC mixture including a monomer, photoinitiator, coinitiator, chain extender, and LCs to which a surfactant can be added. Surfactants are also mentioned in a paper by Natarajan et al, Journal of Nonlinear Optical Physics and Materials, Vol. 5 No. I 89-98, 1996, the disclosure of which is incorporated herein by reference. Furthermore, U.S. Pat. No. 7,018,563 by Sutherland; et al., discusses polymer-dispersed liquid crystal material for forming a polymer-dispersed liquid crystal optical element comprising: at least one acrylic acid monomer; at least one type of liquid crystal material; a photoinitiator dye; a coinitiator; and a surfactant. The disclosure of U.S. Pat. No. 7,018,563 is hereby incorporated by reference in its entirety.

The patent and scientific literature contains many examples of material systems and processes that can be used to fabricate SBGs, including investigations into formulating such material systems for achieving high diffraction efficiency, fast response time, low drive voltage, and so forth. U.S. Pat. No. 5,942,157 by Sutherland, and U.S. Pat. No. 5,751,452 by Tanaka et al. both describe monomer and liquid crystal material combinations suitable for fabricating SBG devices. Examples of recipes can also be found in papers dating back to the early 1990s. Many of these materials use acrylate monomers, including:
R. L. Sutherland et al., Chem. Mater. 5, 1533 (1993), the disclosure of which is incorporated herein by reference, describes the use of acrylate polymers and surfactants. Specifically, the recipe comprises a crosslinking multifunctional acrylate monomer; a chain extender N-vinyl pyrrolidinone, LC E7, photo-initiator rose Bengal, and coinitiator N-phenyl glycine. Surfactant octanoic acid was added in certain variants.
Fontecchio et al., SID 00 Digest 774-776, 2000, the disclosure of which is incorporated herein by reference, describes a UV curable HPDLC for reflective display applications including a multi-functional acrylate monomer, LC, a photoinitiator, a coinitiators, and a chain terminator.
Y. H. Cho, et al., Polymer International, 48, 1085-1090, 1999, the disclosure of which is incorporated herein by reference, discloses HPDLC recipes including acrylates.
Karasawa et al., Japanese Journal of Applied Physics, Vol. 36, 6388-6392, 1997, the disclosure of which is incorporated herein by reference, describes acrylates of various functional orders.
T. J. Bunning et al., Polymer Science: Part B: Polymer Physics, Vol. 35, 2825-2833, 1997, the disclosure of which is incorporated herein by reference, also describes multifunctional acrylate monomers.
G. S. Iannacchione et al., Europhysics Letters Vol. 36 (6). 425-430, 1996, the disclosure of which is incorporated herein by reference, describes a PDLC mixture including a penta-acrylate monomer, LC, chain extender, coinitiators, and photoinitiator.

Acrylates offer the benefits of fast kinetics, good mixing with other materials, and compatibility with film forming processes. Since acrylates are cross-linked, they tend to be mechanically robust and flexible. For example, urethane acrylates of functionality 2 (di) and 3 (tri) have been used extensively for HPDLC technology. Higher functionality materials such as penta and hex functional stems have also been used.

One of the known attributes of transmission SBGs is that the LC molecules tend to align with an average direction normal to the grating fringe planes (i.e., parallel to the grating or K-vector). The effect of the LC molecule alignment is that transmission SBGs efficiently diffract P polarized light (i.e., light with a polarization vector in the plane of incidence), but have nearly zero diffraction efficiency for S polarized light (i.e., light with the polarization vector normal to the plane of incidence).

### Recording Mechanisms for Volume Gratings

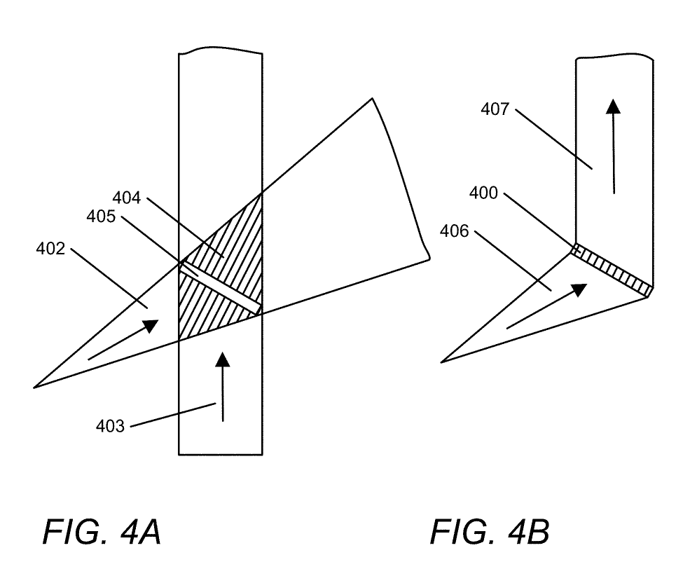

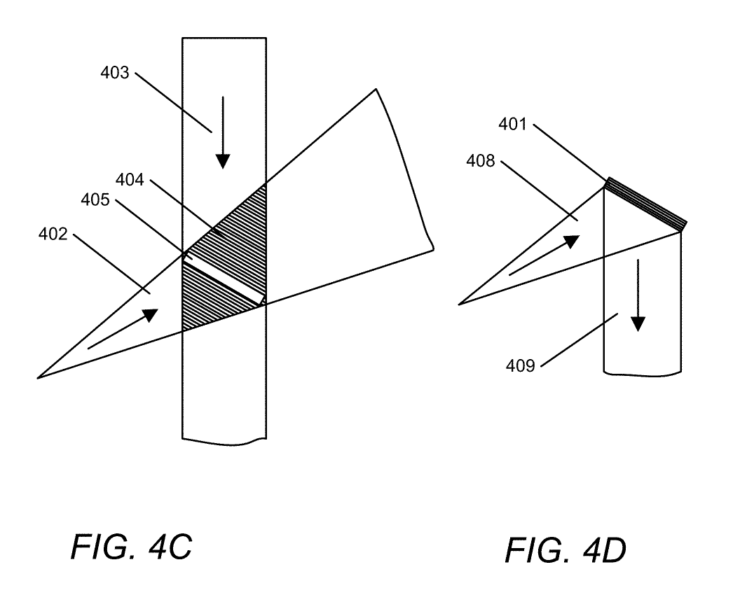

Volume gratings can be recorded in a waveguide cell using many different methods in accordance with various embodiments of the invention. The recording of optical elements in optical recording materials can be achieved using any number and type of electromagnetic radiation sources. Depending on the application, the exposure source(s) and/or recording system can be configured to record optical elements using varying levels of exposure power and duration. As discussed above with regards to SBGs, techniques for recording volume gratings can include the exposure of an optical recording material using two mutually coherent laser beams, where the superimposition of the two beams create a periodic intensity distribution along the interference pattern. The optical recording material can form grating structures exhibiting a refractive index modulation pattern matching the periodic intensity distribution. In HPDLC mixtures, the light intensity distribution results in diffusion and polymerization of monomers into the high intensity regions and simultaneous diffusion of liquid crystal into the dark regions. This phase separation creates alternating liquid crystal-rich and liquid crystal-depleted regions that form the fringe planes of the grating. The grating structures can be formed with slanted or non-slanted fringes depending on how the recording beams are configured. FIGS. 4A-4D conceptually illustrate two-beam recording processes in accordance with various embodiments of the invention. As shown, two methods can be used to create two different types of Bragg gratings—i.e., a transmission grating 400 and a reflection grating 401. Depending on how the two recording beams 402, 403 are positioned, the interference pattern 404 can record either a transmission or a reflection grating in an optical recording material 405. Differences between the two types of gratings can be seen in the orientation of the fringes (i.e., the fringes of a reflection volume grating are typically substantially parallel to the surface of the substrate, and the fringes of a transmission grating are typically substantially perpendicular to the surface of the substrate). During playback, a beam 406 incident on the transmission grating 400 can result in a diffracted beam 407 that is transmitted. On the other hand, a beam 408 that is incident on the reflection grating 401 can result in a beam 409 that is reflected.

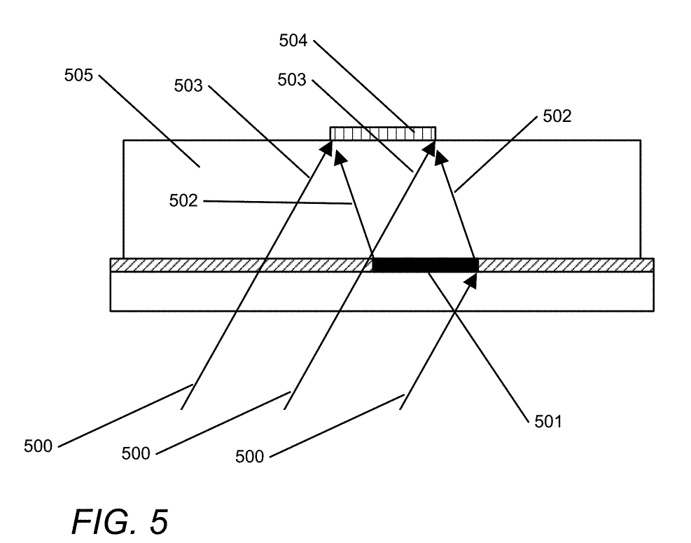

Another method for recording volume gratings in an optical recording material includes the use of a single beam to form an interference pattern onto the optical recording material. This can be achieved through the use of a master grating. In many embodiments, the master grating is a volume grating. In some embodiments, the master grating is an amplitude grating. Upon interaction with the master grating, the single beam can diffract. The first order diffraction and the zero order beam can overlap to create an interference pattern, which can then expose the optical recording material to form the desired volume grating. A single-beam recording process utilizing an amplitude grating in accordance with an embodiment of the invention is conceptually illustrated in FIG. 5. As shown, a beam 500 from a single laser source (not shown) is directed through an amplitude grating 501. Upon interaction with the grating 501, the beam 500 can diffract as, for example, in the case of the rays interacting with the black shaded region of the amplitude grating, or the beam 500 can propagated through the amplitude grating without substantial deviation as a zero-order beam as, for example, in the case of the rays interacting with the cross-hatched region of the amplitude grating. The first order diffraction beams 502 and the zero order beams 503 can overlap to create an interference pattern that exposes the optical recording layer 504 of a waveguide cell. In the illustrative embodiment, a spacer block 505 is positioned between the grating 501 and the optical recording layer 504 in order to alter the distance between the two components.

Although specific methods of recording volume gratings are discussed and shown in FIGS. 4A-4D and 5, recording systems in accordance with various embodiments of the invention can be configured to implement any of a number of methods for recording volume gratings.

Embodiments of Low Haze RMLCM Materials and their Use

Many embodiments are directed to reactive monomer liquid crystal mixture (RMLCM) material systems configured to function as an adhesive in a spacer or spacer less waveguide device, and methods of using such materials in the manufacture of holographic waveguide devices. In various such embodiments, the material systems comprise a RMLCM, which comprises photopolymerizable monomers composed of suitable functional groups (e.g., acrylates, mercapto-, and other esters, among others), a cross-linking agent, a photo-initiator, a surfactant and a liquid crystal (LC). For the purposes of describing the invention a surfactant is defined as any chemical agent that lowers the surface tension of the total liquid mixture.

Turning to the components of the material formulation, any encapsulating polymer formed from any single photo-reactive monomer material or mixture of photo-reactive monomer materials that crosslink and phase separate when combined. Exemplary monomer functional groups usable in material formulations according to embodiments include, but are not limited to, acrylates, thiol-ene, thiol-ester, fluoromonomers, mercaptos, siloxane-based materials, and other esters, etc. Polymer cross-linking may be achieved through different reaction types, including but not limited to optically-induced photo-polymerization, thermally-induced polymerization, and chemically-induced polymerization.

These photopolymerizable materials are combined in a biphase blend with a second liquid crystal material. Any suitable liquid crystal material having ordinary and extraordinary refractive indices matched to the polymer refractive index may be used as a dopant to balance the refractive index of the final RMLCM material. The liquid crystal material may be manufactured, refined, or naturally occurring. The liquid crystal material includes all known phases of liquid crystallinity, including the nematic and smectic phases, the cholesteric phase, the lyotropic discotic phase. The liquid crystal may exhibit ferroelectric or antiferroelectric properties and/or behavior.

Similarly, any suitable photoinitiator, co-initiator, chain extender and surfactant (such as for example octanoic acid) suitable for use with the monomer and LC materials may be used in the RMLCM material formulation.

Various embodiments the reactive monomer liquid crystal mixture may further include chemically active nanoparticles disposed within the LC domains. In some such embodiments, the nanoparticles are carbon nanotube (“CNT”) or nanoclay nanoparticle materials within the LC domains. Embodiments are also directed to methods for controlling the nanoclay particle size, shape, and uniformity are important to the resulting device properties. In addition, the methods for blending and dispersing the nanoclay particles determine the resulting electrical and optical properties of the device are also provided. A full discussion of such nanoparticles and their use in RMLCM materials may be found in PCT App. No. PCT/GB2012/000680, the disclosure of which is incorporated herein by reference.

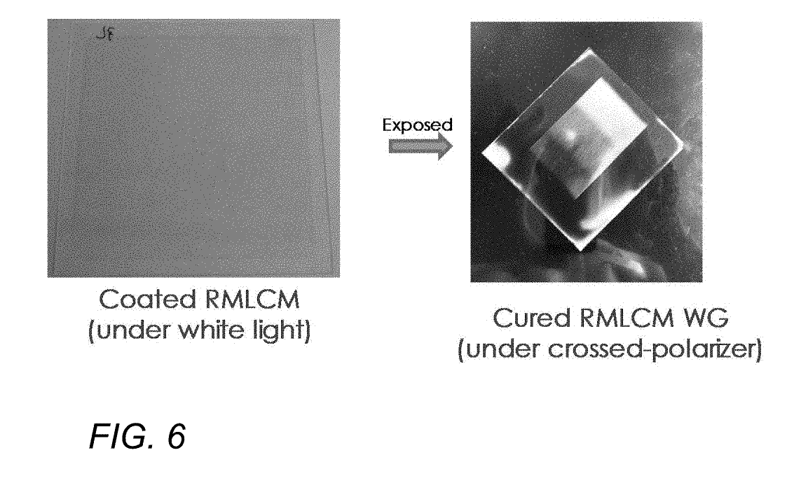

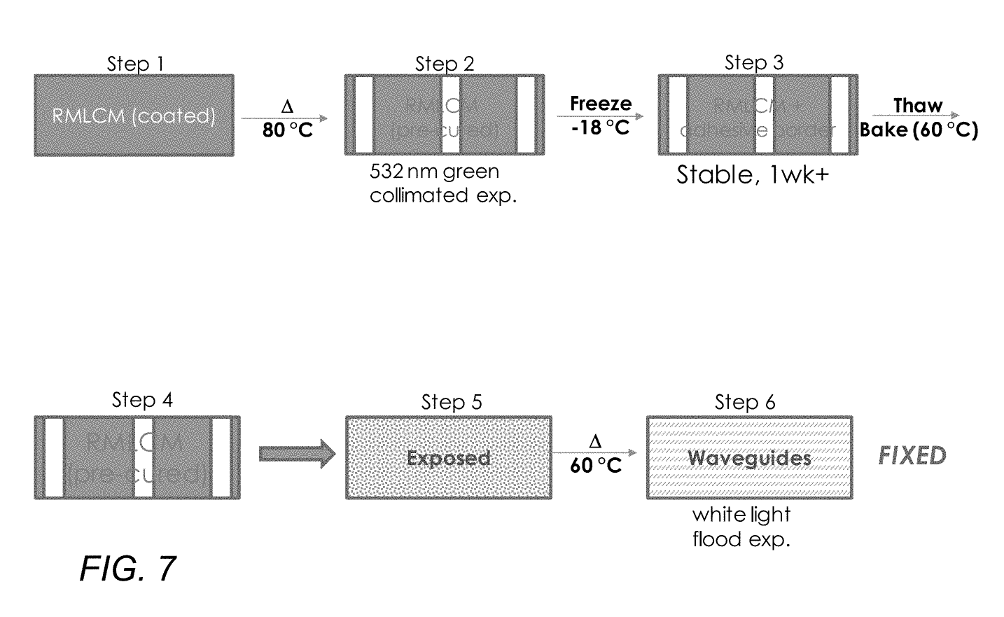

Embodiments are also directed to methods of manufacturing waveguide devices using RMLCM materials as adhesives. As shown in FIG. 6, applying such materials as adhesives using conventional application techniques can lead to hazy regions when cured. Accordingly, many embodiments are directed to methods of pre-curing RMLCM materials to improve clarity, as shown in FIG. 7. The proposed material and fabrication process generally comprise the steps of:
The RMLCM is preheated in steps prior to cell filling to initiate a cross link of the polymer matrix and improve performance. (Note that the formulation of the RMLCM material may be chosen to ensure reduction of ingredient evaporation during filling of the RMLCM cell by judicious choice of high molecular weight fluoromonomers and compensation methods. This is important because standard materials can boil off within the vacuum fill duty cycles commonly used in existing processes. By tightly controlling the process and calculate the boil-off amount for several typical cycle times and thereby compensate the particular vacuum fill machine pump-down and fill cycle. In some cases it is necessary to increase concentration of ingredients beyond the level that is optimal for best device performance.)
During the fill, a multistep vibration procedure may be used to combine the LC and polymer ingredients to ensure quick filling.
Once filled the RMLCM material is exposed with a light source to pre-cure the material. In many embodiments a dye, such as, for example, a green sensitive dye is added to the materials. Regardless of the specific dye used a collimated light source is used to pre-cure the material.
The filled and pre-cured cells are frozen and stored in their frozen state after vacuum filling. Providing frozen pre-exposed blank cells has several benefits in the subsequent exposure process as described in PCT Application No. PCT/GB2012/000680, the disclosure of which is incorporated herein by reference.
When the cells are ready for use the pre-cured cells are thawed and exposed using a holographic laser exposure procedure.
The exposed cells are cured and thermally exposed to improve phase separation and hence diffraction efficiency and prevent any voltage creep by arresting any active ingredients not already completely polymerized.

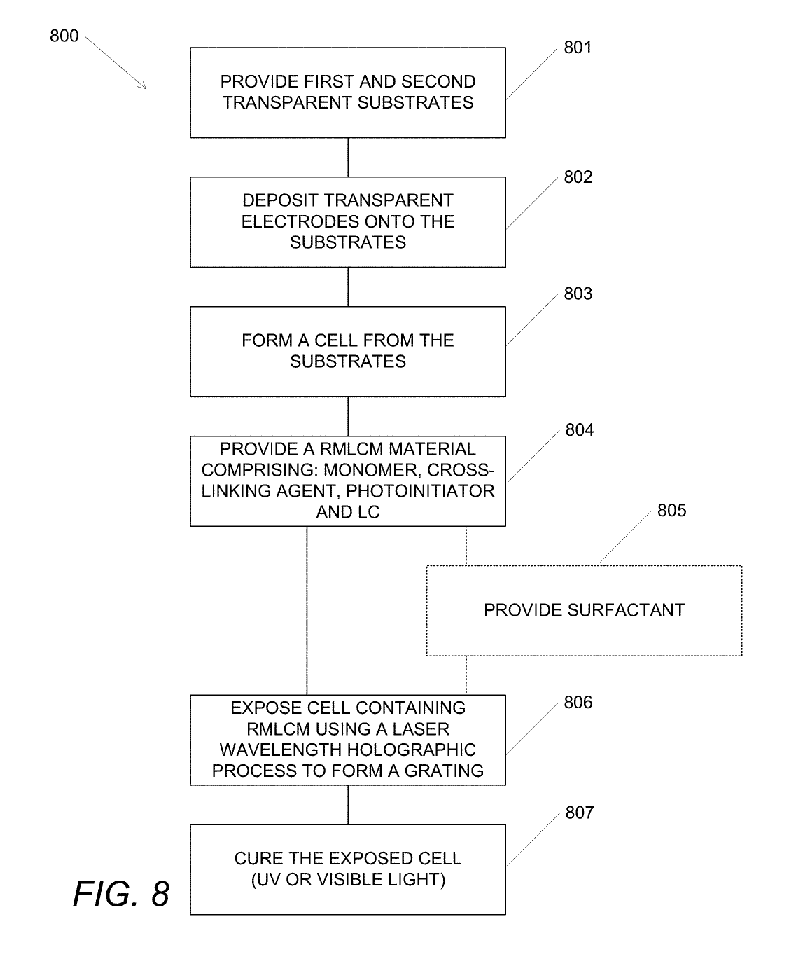

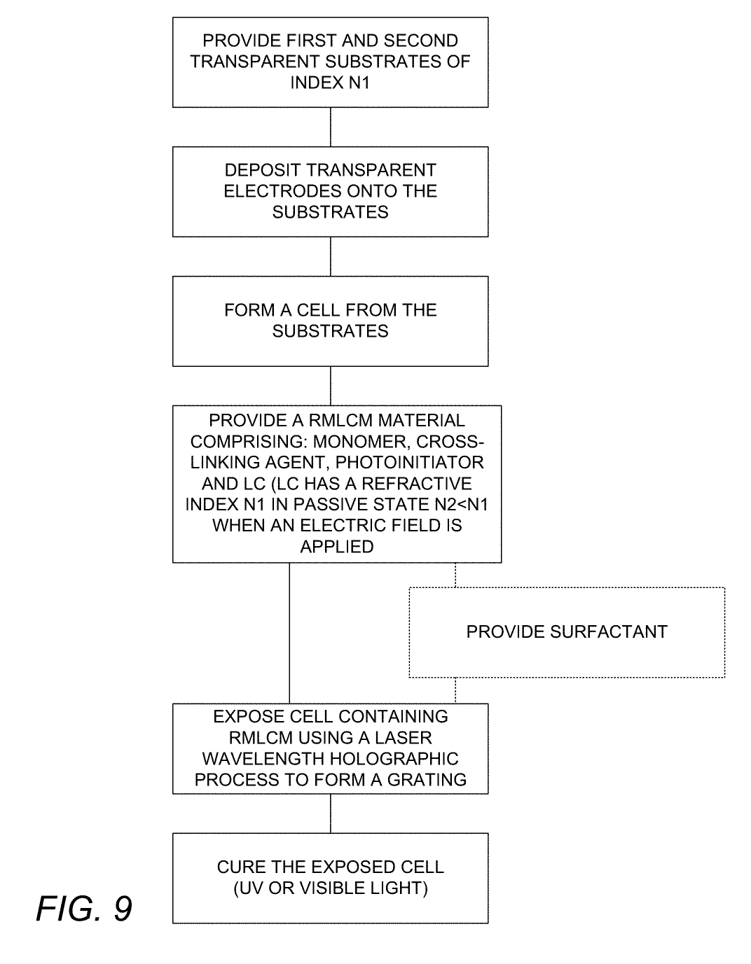

According to many embodiments, such cells can be incorporated into any holographic waveguide. Flowcharts of such methods, in accordance with embodiments, are shown in FIG. 8. As shown, the process 800 includes providing (801) first and second transparent substrates. Transparent electrodes can be deposited (802) onto the substrates. A cell can be formed (803) from the substrates. An RMLCM material can be provided (804). A surfactant can optionally be provided (805). The cell can be exposed (806) to form a grating. The exposed cell can be cured (807). Referring to the flow diagram of FIG. 9, a method of fabricating a reversed mode HPDLC. As shown, the method is similar to that of FIG. 8 but differs in the type of material utilized.

Regardless of the specific type of waveguide to be formed, in many embodiments a method of forming the RMLCM material comprises a method of uniformly blending the constituents to avoid phase separation and produce a single layer of liquid with measurable solution properties, including, but not limited to, heating, stirring, sonication, agitation, degassing and filtration. In various embodiments, the mixing methods allow components that would otherwise be separable such as, for example, photosensitive dyes, and solid components (e.g., nanoparticles) to remain stabilized in the material formulation such as by non-covalent/Van der Waals interactions or adsorbed in pools of monomers and LCs.

It will be understood that the photo-initiator may operate in any desired spectral band including the in the UV and/or in the visible band. The preferred substrates are of high optical quality, for example Corning 1737 glass, and coated with a transparent conductive layer, for example indium-tin-oxide ITO). The cell is subsequently exposed to patterned light, and a structured phase separation occurs during photopolymerization, resulting in a holographically formed polymer dispersed liquid crystal (H-PDLC) structure. Said patterned light may be provided by means of conventional laser interference processes using in holographic recording. Alternatively, a masking process may provide said patterned light.

In various embodiments plastic substrates may be used. Two currently available plastic substrates materials are a cyclic olefin copolymer (COC) manufactured by TOPAS Advanced Polymers and sold under the trade name TOPAS. The other was a cyclic olefin polymer (COP) manufactured by ZEON Corporation and sold under the trade names ZEONEX and ZEONOR. Transparent conductive coatings (TCC), formed from ITO for example, applied to the above plastics have been found to provide sufficient resistivity, surface quality, and adhesion. Imperfections are known to have no impact on overall cell performance. ITO suffers from the problem of its lack of flexibility. Given the rugged conditions under some SBG devices may operate, it is desirable to use a flexible TCC with a plastic substrate. In addition, the growing cost of indium and the expense of the associated deposition process also raise concerns. Carbon nanotubes (CNTs), a relatively new transparent conductive coating, are one possible alternative to ITO. If deposited properly, CNTs are both robust and flexible. Plus, they can be applied much faster than ITO coatings, are easier to ablate without damaging the underlying plastic, and exhibit excellent adhesion. In various embodiments an environmental coating is applied to an external surface of at least one of the substrates. For example, a TEC 2000 hard coat may be used as an environmental seal of the SBG cell and as a primer for better adhesion of the conductive coatings such as ITO and CNT. It has also been demonstrated that double side coated TEC 2000 TOPAS and ZEONEX SBG cells perform very well optically and are environmentally stable.

In other embodiments first and second substrates are fabricated from a polycarbonate or similar plastics. In various embodiments the transparent electrodes are fabricated from PDOT conductive polymer. This material has the advantage of being capable of being spin-coated onto plastics. Typically a PDOT conductive polymer can achieve a resistivity 100 Ohm/sq.

In one embodiment of the invention the transparent electrodes are fabricated from CNT. In one embodiment of the invention at least one substrate surface abutting said reactive monomer liquid crystal mixture has a surface relief structure. The surface relief structure may comprise one or two dimensional micro prisms disposed in a regular patter or randomly. The micro prism may have different sizes. The surface relief structure may comprise at least one waveguide cavity. In one embodiment of the invention CNT is used to form a printed microstructure using a lift-off stamping process. An exemplary CNT material is the one provided by OpTIC (Glyndwr Innovations Ltd.) St. Asaph, Wales, United Kingdom.

Although the invention has been discussed in relation to SBG devices the HPDLC material system and fabrication process described herein may also be applied to any type of HPDLC grating device including SBGs and subwavelength gratings. The devices may be transmissive or reflective and be used with guided beams or in free-space applications. The invention may be used to provide more efficient waveguide devices. Such waveguide devices may be used in Optical Add Drop Multiplexers, Variable Optical Attenuators and many other applications. The basic invention is not restricted to any particular application and may be used to provide switchable grating devices in any switchable grating devices or other holographic waveguide device.

### DOCTRINE OF EQUIVALENTS

Although specific systems and methods are discussed above, many different embodiments can be implemented in accordance with the invention. It is therefore to be understood that the present invention can be practiced in ways other than specifically described, without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents. Although specific embodiments have been described in detail in this disclosure, many modifications are possible (for example, variations in sizes, dimensions, structures, shapes and proportions of the various elements, values of parameters, mounting arrangements, use of materials, colors, orientations, etc.). For example, the position of elements may be reversed or otherwise varied and the nature or number of discrete elements or positions may be altered or varied. Accordingly, all such modifications are intended to be included within the scope of the present disclosure. The order or sequence of any process or method steps may be varied or re-sequenced according to alternative embodiments. Other substitutions, modifications, changes, and omissions may be made in the design, operating conditions and arrangement of the exemplary embodiments without departing from the scope of the present disclosure.

What is claimed is:

1. A method of forming a waveguide cell, the method comprising:
providing first and second transparent substrates;
forming a cell from the substrates;
providing a reactive monomer liquid crystal mixture material comprising:
photopolymerizable monomers,
a cross-linking agent,
a photoinitiator, and
liquid crystals;
combining at least one of the monomers and at least one of the liquid crystals;
heating the reactive monomer liquid crystal mixture material to a temperature sufficient to initiate crosslinking of the polymer matrix; and
depositing the heated reactive monomer liquid crystal mixture material into the cell.

2. The method of claim 1, further comprising exposing the filled cell to a light source to pre-cure the reactive monomer liquid crystal mixture material.

3. The method of claim 2, further comprising cooling the pre-cured cell to freeze the reactive monomer liquid crystal mixture material material.

4. The method of claim 3, further comprising exposing the cell using a laser wavelength holographic process.

5. The method of claim 4, further comprising heating the exposed cell to an elevated temperature and curing the exposed cell.

6. The method of claim 1, wherein the at least one of the monomers and the at least one of the liquid crystals are combined using a vibrational technique.

7. The method of claim 1, wherein the heated reactive monomer liquid crystal mixture material is deposited into the cell using a multi-step vibrational technique.

8. The method of claim 1, wherein the deposited heated reactive monomer liquid crystal mixture material functions as an adhesive in the cell.

9. The method of claim 1, wherein the reactive monomer liquid crystal mixture material further comprises at least one nanoparticle.

10. The method of claim 9, wherein the at least one nanoparticle comprises a one of a carbon nanotube or a nanoclay nanoparticle.
